(19) United States
(12) Patent Application Publication
(10) Pub. No.: US 2007/0166956 A1
(43) Pub. Date: Jul. 19, 2007

(54) Method for producing electronic chips consisting of thinned silicon

(76) Inventor: Pierre Blanchard, Echirolles (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/582,711

(22) PCT Filed: Nov. 18, 2004
(86) PCT No.: PCT/EP04/53003

§ 371 Date: Jun. 12, 2006

(30) Foreign Application Priority Data
Dec. 12, 2003 (FR) 03/14595

(51) Int. Cl. H01L 21/30

(52) U.S. Cl. 438/459

(57) ABSTRACT

The invention relates to the fabrication of color image sensors formed on a thinned silicon substrate.

The sensor is fabricated from a semiconductor wafer (10) comprising, on its front face, a thin active layer (12) of semiconductor material, and for this purpose etched layers are formed on the active layer, the wafer is bonded by its front face onto a support substrate (40), the semiconductor wafer is thinned down by its backside, then layers of material are deposited and etched on its backside thus thinned. Also provided are narrow vertical trenches (20, 22, 24, 26) that are etched into the wafer by its front face, before the bonding operation, these trenches extending into the wafer over a depth approximately equal to the residual semiconductor wafer thickness that will remain after the thinning operation, the trenches being filled with a conducting material isolated from the active layer and forming conducting vias (20′, 22′, 24′, 26′) between the front face and the backside of the thinned layer. The purpose of the trenches is to establish electrical connections between the front face and the backside of the thinned wafer. They can also serve as markers for alignment of the front-face features with those on the backside. Lastly, they can be used to electrically isolate regions of active layers from one another.

### CROSS-REFERENCE TO RELATED APPLICATIONS

The present Application is based on International Application No. PCT/EP2004/053003, filed on Dec. 12, 2003, which in turn corresponds to FR 03/14595 filed on Dec. 12, 2003, and priority is hereby claimed under 35 USC §119 based on these applications. Each of these applications are hereby incorporated by reference in their entirety into the present application.

### FIELD OF THE INVENTION

The invention relates mainly to the manufacture of color image sensors fabricated on a thinned silicon substrate. The thinning down of the silicon on which the image sensor is made is a technique that allows the colorimetry to be improved by minimizing interference between neighboring image points corresponding to different colors; the interference is reduced thanks to the fact that the color filters, which are used to separate the primary components of light, can be deposited on the backside rather than on the front face of a silicon wafer which then brings them closer to the photosensitive regions formed in the silicon; the front face is that on which the deposition and etching operations are carried out for layers forming the main part of the photodetector matrix and of its control circuits.

### BACKGROUND OF THE INVENTION

A color image sensor on thinned silicon may be fabricated in the following manner: starting from a semiconductor wafer (generally silicon), the following operations are carried out on its front face: masking, impurity implantation, deposition of temporary or permanent layers of various composition, etching of these layers, thermal processing, etc.; these operations allow a matrix of photosensitive pixels and electrical signal processing circuits associated with these pixels to be defined; the wafer is then bonded by its front face against the front face of a support substrate; the major part of the thickness of the semiconductor wafer is then removed (this is the thinning operation), leaving a thin semiconductor layer remaining on the support substrate comprising the photosensitive regions and the associated circuits; subsequently, various layers are deposited and etched on the backside of the semiconductor layer thus thinned, among which are for example an opaque metal layer and a color filter layer.

It is understood that, with this process, the color filters are not located on top of a stack of insulating and conducting layers that may have been deposited (using CMOS technology or another technology) onto the photosensitive regions in the course of the fabrication of the semiconductor wafer. On the contrary, the filters are placed underneath the photosensitive regions, opposite to the insulating and conducting layers which are then on the other side of the photosensitive regions. This means that when the sensor is used in a camera, the light will arrive on the backside of the sensor, will pass through the color filters and will reach the photosensitive regions directly, without having to pass through the stack of insulating and conducting layers.

It is this proximity between the photosensitive regions and the color filters that provides an enhanced colorimetry, as long as the thinning is very pronounced: the residual thickness of silicon after thinning is approximately 5 to 20 microns.

This fabrication process poses two types of problem: the first problem is a problem of electrical contact between the outside of the sensor and the circuitry which has been etched onto the front face of the semiconductor wafer, which front face is no longer accessible once the semiconductor wafer has been bonded onto the support substrate; fabrication steps must therefore be included in order to make this access possible despite the bonding operation and these fabrication steps must be industrially economically viable and efficient; the second problem is a problem of alignment precision of the etching steps performed on the backside with respect to the circuit features that may have been etched, before this bonding operation, onto the front face: the alignment of features over successive layers on the same face is a conventional technique; the alignment of features situated on two different faces, one of which is no longer accessible, is a more difficult problem.

The goal of the present invention is to provide a fabrication process that simultaneously provides a solution to both of these two problems. This process may particularly advantageously be applied to the fabrication of color image sensors, but it is more generally applicable to the fabrication of all kinds of electronic chips formed from thinned silicon wafers.

### SUMMARY OF THE INVENTION

According to the invention, there is proposed a process for the fabrication of electronic chips from a semiconductor wafer comprising, on its front face, a thin active layer of semiconductor material, this process comprising the formation of etched layers on the active layer, the bonding of the wafer by its front face onto a support substrate, the thinning down of the semiconductor wafer by its backside, then the deposition and the etching of layers of material onto the backside thus thinned, the process being characterized in that narrow vertical trenches are etched into the wafer by its front face, before the bonding operation, these trenches extending into the wafer over a depth approximately equal to the residual semiconductor wafer thickness that will remain after the thinning operation, the trenches being filled with a conducting material isolated from the active layer and forming conducting vias between the front face and the backside of the thinned wafer.

By the expression “narrow vertical trenches” is understood trenches with parallel vertical sidewalls whose width is several times smaller than the depth and than the length. By the expression “filled with a conducting material” is understood the fact that the conducting material is not only deposited on the walls of the trench but it also fills the open space when the trench is formed.

These vertical trenches, which therefore extend just about as far as the future backside of the wafer, can also function as optical alignment markers for photoetching operations on the backside; this is because they are precisely positioned with respect to the front-face patterns, they are vertical and, thanks to the differences in optical index between the semiconductor material and the materials that form the conducting vias, they are visible on the backside after thinning since they open out directly onto this backside or else they come very close to this backside.

The trenches used for alignment markers are, in principle, nonfunctional with regard to the electronic circuitry: they are situated outside of this circuitry, and even sometimes outside of the surface reserved for the chips on the wafer. They are nevertheless formed like the trenches that have the functional role of establishing electrical connections between the front face and the backside. Both the trenches to be used for markers, on the one hand, and the trenches to be used as conducting vias, on the other, are etched in the same photoetching operation, and the trench wall insulating and trench filling operations are also simultaneous for the alignment markers and the functional vias used to establish contacts between front face and backside.

### BRIEF DESCRIPTION OF DRAWINGS

Other features and advantages of the invention will become apparent upon reading the detailed description that follows and which is presented with reference to the appended drawings in which:

FIGS. 1 to 9 show the successive fabrication steps for a color image sensor chip;

FIG. 10 shows the finished chip;

FIGS. 11 and 12 show, in cross section and as a top view respectively, the structure of a contact pad of the chip.

FIG. 13 shows a variant embodiment.

### DESCRIPTION OF PREFERRED EMBODIMENTS

FIG. 1 shows a semiconductor wafer, in principle made entirely from silicon although this is not necessarily the case, on which an array of individual image sensor die will be fabricated. The wafer will be diced up into individual chips at the end of the fabrication process. Each sensor comprises a rectangular matrix of photosensitive regions and the associated circuits allowing the charges photo-generated at each pixel of the matrix to be collected and an electronic signal representing the image received by the sensor to be established. The sensor fabrication technology is preferably, but not necessarily, a CMOS (Complementary Metal Oxide Semiconductor) technology.

The semiconductor wafer in FIG. 1 is preferably formed from a silicon substrate 10, highly doped with p-type impurities, on the front face of which an epitaxial layer 12, also of the p type but much more lightly doped, is formed. The epitaxial layer is the active layer in which the photosensitive regions are formed. Typically, the substrate has a thickness of a few hundred microns and the epitaxial layer only around ten microns (preferably between 5 and 10 microns but possibly as much as 30 microns). Generally speaking, in order to improve readability, the figures are not to scale.

The fabrication process involves, on the one hand, various diffusion and implantation operations into the silicon from the upper face or front face of the wafer, in order to form notably the photosensitive regions, and, on the other, successive deposition and etching operations for conducting and insulating layers.

Prior to the deposition and etching of these electrically functional layers, steps specific to the present invention will be carried out. It will be noted that it could also be envisioned to carry them out after these deposition and etching operations or at an intermediate step, but it is preferred that these steps be performed at the beginning of the fabrication process.

These specific steps consist in forming deep vertical apertures, in the form of narrow trenches, through practically the whole of the thickness of the silicon of the epitaxial layer 12.

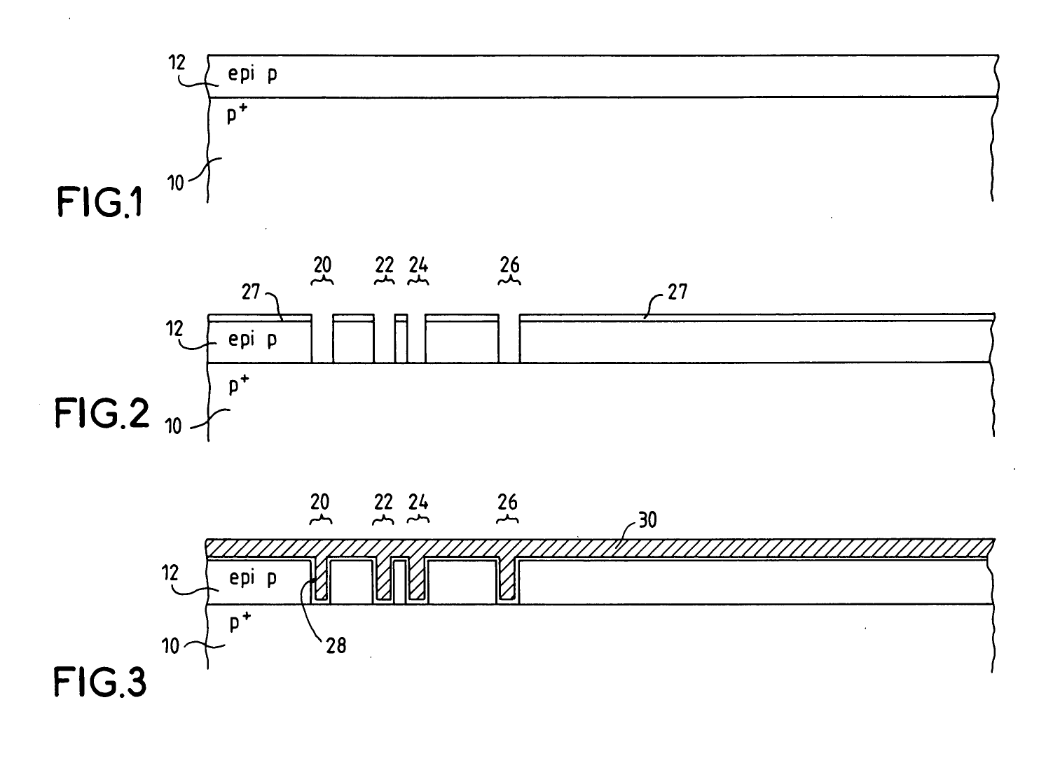

FIG. 2 shows, by way of illustration, four apertures 20, 22, 24, 26 thus formed on the front face of the wafer. In the embodiment described, some of these apertures (the leftmost opening 20 in FIG. 2) are designed to form alignment markers, others (apertures 22 and 24) are designed to form electrical contacts, and yet others (the rightmost opening 26) can have other functions (insulation between various silicon regions). They are formed in the same fabrication step.

The apertures are generally in the form of narrow vertical trenches, in other words of greater depth than width. The narrowness is needed since, as will be seen, these trenches are filled later on and a narrow trench is more easily filled than a wide opening. Thus, for an electrical contact opening that must allow a high current to flow, the formation of several neighboring narrow trenches will be preferred rather than a wide opening, as will be seen below; this is why there are two apertures 22 and 24, that are nevertheless intended to form a single electrical contact, shown next to one another. The width of the trench is for example around 1 to 4 microns for a depth of 5 to 30 microns. The length of the trenches depends on the function of the trenches; it can typically be several tens of microns depending on the requirements, either in terms of optical visibility (for the alignment markers), or in terms of contact surface area needs (for the contact apertures).

The depth of the trenches is equal to the depth of the epitaxial layer or slightly deeper or slightly shallower. For the alignment markers, these markers will remain visible later on even if the trenches do not go down as far as the base of the epitaxial layer: there can be 1 to 3 microns of epitaxial silicon remaining between the bottom of the trench and the base of the epitaxial layer without this having any significant optical effect (since the epitaxial layer is relatively transparent). For the electrical contacts and the insulation, it is better that the depth of the trenches goes as far as the boundary between the epitaxial layer 10 and the substrate, or even slightly beyond, so as not to have to subsequently etch a thickness of epitaxial layer. If alignment marks and contacts or isolation trenches are simultaneously provided, the same depth will be given to all the trenches and this depth will preferably be equal to the depth of the epitaxial layer. In the figures, the trenches are shown as having exactly the same depth as the epitaxial layer.

The formation of the trenches at the desired location is preferably carried out by surface oxidation of the epitaxial layer, hence the creation of an oxide layer 27, then resist masking, photoetching of the resist, etching of the silicon dioxide in the resist apertures, removal of the resist and etching of the silicon by anisotropic reactive ion etching at the places where the silicon is not protected by the oxide. The current technology can produce narrow vertical trenches of 1 to 3 microns width for a depth of 10 microns or more.

The trenches thus formed will be refilled, on the one hand for planarizing the surface with a view to later photoetching steps and, on the other, to form conducting vias for the contact apertures.

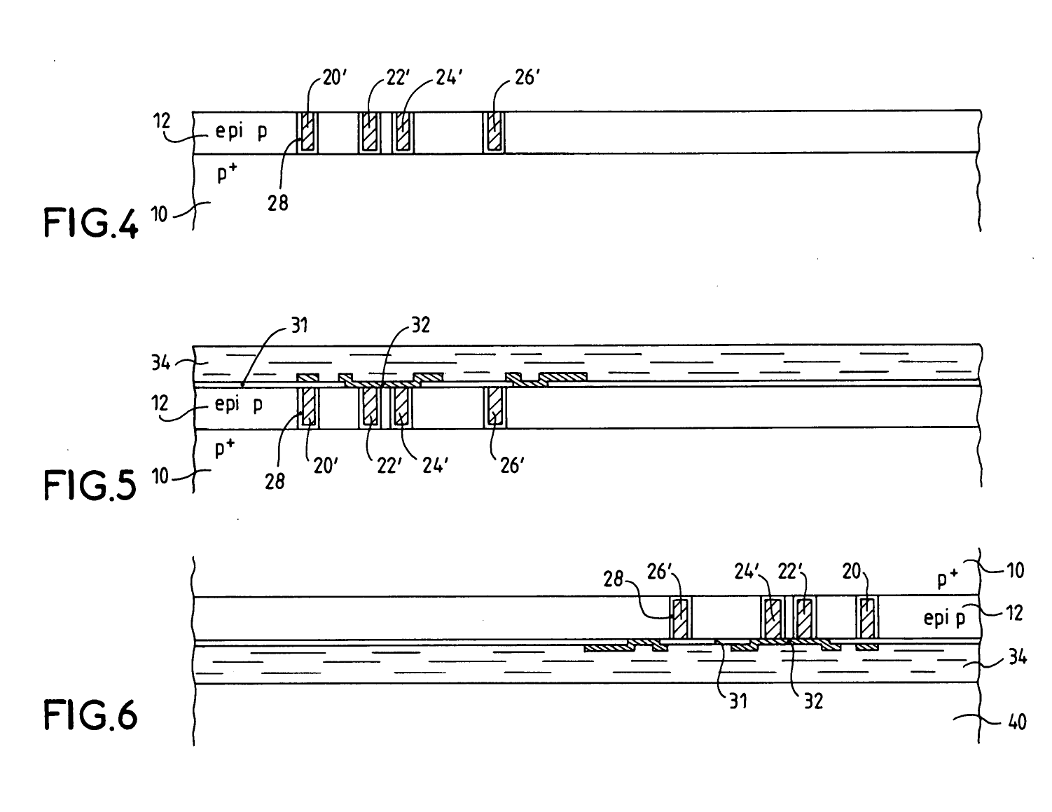

The preferred solution (FIG. 3) then consists, firstly, in surface oxidation of the wafer so as to coat its surface and the walls of the trenches with a thin film (a few tens of nanometers thickness) of insulating silicon dioxide 28, then in depositing highly-doped, hence conducting, polycrystalline silicon 30. The deposition fills the narrow trenches and coats the surface of the wafer. The doped polycrystalline silicon is then removed over a vertical thickness that corresponds to the thickness deposited on the wafer. The silicon remains in the trenches (FIG. 4) and forms conducting vias 20′, 22′, 24′, 26′ between the front face of the epitaxial active layer 12 and the backside of this layer. In relation to the apertures 22 and 24, these vias will effectively play the role of conducting vias in order to establish electrical contacts, but not necessarily in relation to the apertures 20 and 26.

The steps for fabricating the image sensor itself with its associated circuits are then carried out, in other words the doping steps, the implantations into the epitaxial layer, the thermal processing steps, the conducting and insulating layer deposition operations and the photoetching steps required each time, etc. The details of this fabrication process, which is now conventional, will not be entered into here. Only shown in FIG. 5 are:

on the one hand, an insulating layer 31 that covers the surface of the wafer and which is locally opened up for the provision of contacts, notably on top of the conducting vias 22′ and 24′;

on the other hand, a conducting layer 32, of metal or highly-doped polycrystalline silicon, whose purpose is to establish interconnects within the circuit and which notably comes into contact, through the insulating layer 31, with the conducting vias 22′ and 24′;

and lastly, a stack of multiple insulating and conducting layers, that are photoetched according to the appropriate patterns in order to form the sensor and its associated circuits, is shown globally in the form of one layer 34.

During the photoetching steps, the trenches 20, filled with polycrystalline silicon 30 isolated by the insulating layer 28 and transformed into vias 20′, are used as optical alignment markers for the photoetching operations that follow the formation of these trenches. All the etching features produced on the front face of the semiconductor wafer are therefore progressively aligned on top of one another by taking the trenches 20 as initial reference. The conducting vias 20′ are visible by reason of the differences in index between the silicon, polycrystalline silicon and silicon dioxide materials of which they are composed.

The end of the process for deposition and etching of the layers on the front face generally comprises a planarization step, in other words a deposition step for a layer that fills the relief level differences caused by the successive deposition and etching steps. It is therefore assumed that the upper part of the layer 34 is a plane surface, for example achieved by means of a planarizing silicon dioxide or polyimide deposition.

The processing of the front face of the semiconductor wafer is now finished. The wafer is then bonded onto a support substrate 40 (FIG. 6). This bonding is via the front face of the wafer, in other words it is the planarized front face that is bonded onto a plane face of the support substrate. The wafer 10 with its epitaxial layer 12 and its photoetched layers 34 is therefore shown upside down, front face downward, in FIG. 6 and the following figures.

The bonding of the silicon wafer may be effected by several means, the simplest means being by a molecular bonding, the extreme flatness of the surfaces in contact generating very high contact forces. Bonding with a bonding material is also possible. Still further methods are also possible.

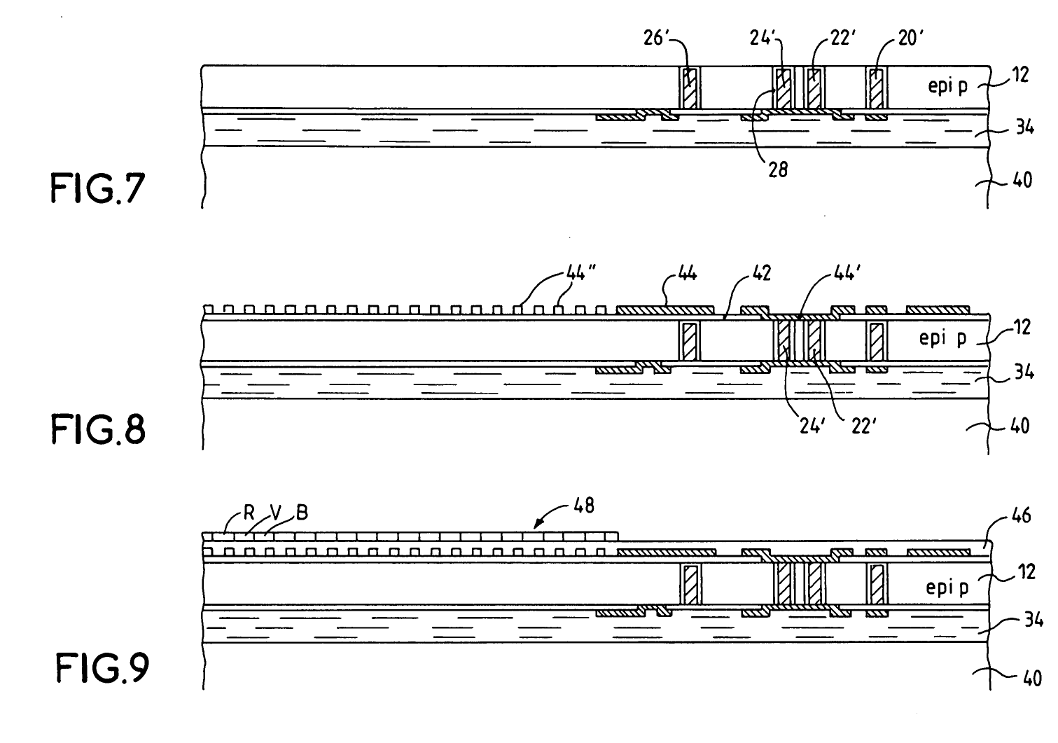

After bonding the silicon wafer by its front face onto the support substrate, the major part of the thickness of the silicon wafer is removed from its backside (top in FIG. 6) so as to only leave the epitaxial active layer remaining 12 (FIG. 7).

The thinning operation can be performed by mechanical abrasion finished by a chemical polishing, or by chemical-mechanical polishing, or by only chemical polishing, or by other processes.

The wafer is thinned flush with the bottom of the trenches 20, 22, 24, 26 that have been etched out and refilled in the preceding steps.

The surface of the wafer (still referred to as backside by reference to the front face now bonded onto the support substrate) can now undergo layer deposition and layer etching operations.

For the alignment of the etching patterns of these layers, the optical markers formed by the flush exposed bottoms of the vias 20′, formed in the trenches 20, are used. This bottom is visible even if a thin layer of insulation 26 remains; it would actually still be visible even if a thickness of 1 or 2 microns of epitaxial silicon were remaining between the bottom of the via and the backside of the wafer. The optical markers thus formed are precisely positioned with respect to the patterns on the front face since the trenches are vertical.

Amongst the layers deposited and photoetched onto the backside, first of all there is an insulating layer 42 (FIG. 8) locally opened up at the locations of the vias 22′ and 24′. When this insulating layer is opened up, the insulating bottom of the vias (layer 28) is also opened up. If the trenches were etched down to a depth slightly shallower than that of the epitaxial layer, complementary steps for the etching of the epitaxial layer would be included in order to complete the formation of the conducting vias.

There is also at least one conducting layer 44, preferably of metal (notably aluminum) whose purpose is notably to form interconnects and contact pads designed to provide external connections to the chip when the fabrication process is finished. In the case of an image sensor, this layer can also serve as a masking layer to protect sensor regions (within the pixel matrix or within the drivers) from the light which, owing to the fact that silicon is naturally photosensitive, may be affected by light. This interconnection layer 44 is shown not only in the form of a contact pad 44′, which comes into direct contact with the vias 22′ and 24′, but also in the form of periodic masking patterns 44″ within a region corresponding to the pixel matrix of the image sensor (left-hand side of FIG. 8).

The contact pad 44′ could serve as a solder pad for a connecting wire, or else be connected via an interconnection of the layer 44 to a connecting wire solder pad situated not on top of the vias 22′ and 24′ but at another location (the pads are generally on the periphery of the chip); it is however simpler to locate the solder pads directly on top of the vias which are then at the periphery of the chip.

For a color image sensor, aside from the metal layer 44, the deposition and etching operations on the backside notably comprise the successive deposition and etching of three color filter layers arranged in a matrix pattern in order to define adjacent pixels corresponding to the primary colors of light.

The process for depositing the color filters is as follows: deposition of a first planarization layer 46 onto the entirety of the backside of the wafer. Deposition and etching of a first filter color, then of a second and then of a third.

These filter layers are symbolized in FIG. 9 by a layer 48 on top of a region being considered as the image capture region of the sensor.

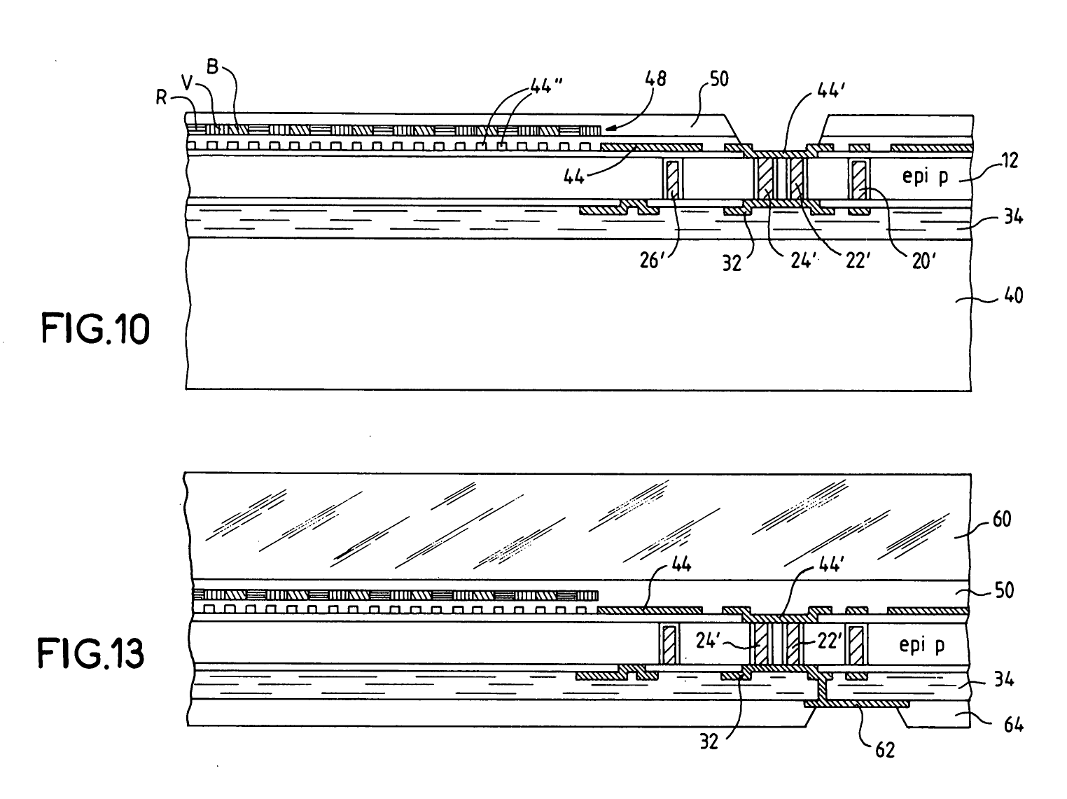

FIG. 10 shows the finished wafer. The filter layer 48 is coated with a final planarization and protection layer 50, which is an insulating layer. It is opened up at the locations of the solder pads 44′ such that a connecting wire can be soldered between this pad and a unit in which the chip will be installed.

The finished wafer is conventionally diced up into individual chips.

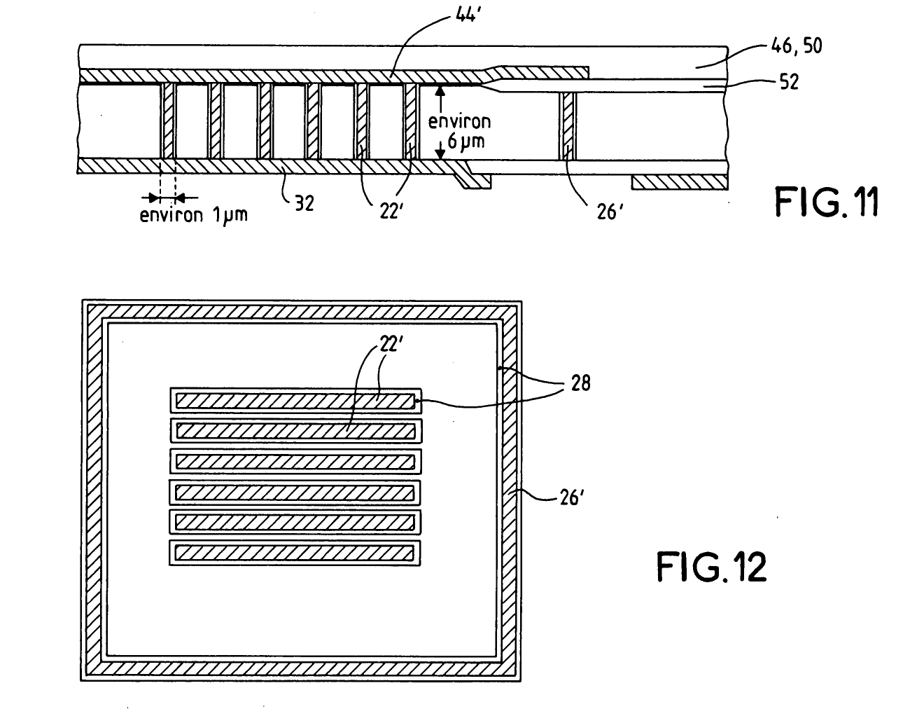

FIGS. 11 and 12 show the detail of the formation of an external connection contact pad 44′ connected by conducting vias to a conducting region 32 which is formed during the fabrication steps, prior to bonding onto the substrate 40, on the front face of the wafer.

The pad is composed of a rectangular surface that covers two groups of trenches: the first group is composed of a series of parallel trenches formed into conducting vias 22′ that all come into contact at the bottom with the region 32 and at the top with the pad 44′; the second group is an isolation trench 26′ that surrounds the whole of the epitaxial layer region situated under the external connection pad 44′. This isolation trench is formed exactly like the conducting vias 22′ but is not connected to an upper conductor and a lower conductor. Its function is to electrically isolate the whole of the epitaxial layer region situated under the contact pad 44′ from the rest of the epitaxial layer. Such isolation trenches could be provided in order to electrically isolate various regions of epitaxial layer from one another. For example, a trench could simultaneously isolate from the rest of the layer a contact pad and an amplifier whose output is formed by the pad.

Here, the width of the trenches is around 1 micron, the thickness of the epitaxial layer and hence the depth of the trenches is around 6 microns, and the lateral dimensions of the pad are around 100 microns.

In FIG. 11, which is magnified with respect to the preceding figures, a layer of thermal silicon dioxide 52 is shown in order to demonstrate that the steps carried out on the front face may, of course, include conventional thermal oxidation steps.

An important variant of the invention may be envisioned. Indeed, in what has just been described, the image sensor chip finally formed is considered to have contact pads on the face that receives the light, which face is referred to as backside of the semiconductor wafer. However, after the deposition of the final planarization layer 50, the wafer could also again be bonded onto another, transparent, support substrate 60 made of glass or quartz. The light then arrives through this glass or quartz substrate. The support substrate 40 then becomes superfluous, since the glass or quartz substrate provides the mechanical rigidity of the wafer.

The support substrate 40 is then eliminated or removed, by mechanical and/or chemical abrasion/polishing, until flush, or virtually so, with the upper part of the assembly of layers 34. These layers notably comprise interconnection layers and they can, in particular, comprise a final metal layer comprising contact pads for soldering connection wires. In this case, the pads 44′ are not used for the contact with the outside, since they are no longer accessible because of the glass or quartz support substrate, but the pads of the assembly 34 instead.

This solution replaces as upper face of the chip the front face on which the deposition, implantation and etching steps used to form the image sensor have been conventionally carried out. Although the backside is no longer accessible, the trenches made at the beginning of the process allow easy access, via the pads 44′, the conducting vias 22′, 24′, the conducting regions 32, and other conducting layers of the assembly 34, to the light masking metallization 44 which would otherwise be inaccessible. This is important since it is desirable to be able to control and monitor the potential of this backside metallization.

FIG. 13 shows the structure of a sensor chip thus fabricated, on which can be seen, aside from the elements already mentioned with reference to FIGS. 1 to 9, the transparent substrate 60, an external solder pad 62, connected through the layers of the assembly 34 to the conducting layer 32 and hence to the layer 44, and a passivation and protection layer 64 opened up at the location of the pad 62. The pad 62 is formed at the end of the step shown in FIG. 5.

1-15. (canceled)

16. A process for the fabrication of electronic chips from a semiconductor wafer comprising, on its front face, a thin active layer of semiconductor material, the process comprising steps of:
formatting of etched layers on the active layer;
bonding the wafer by its front face onto a support substrate;
thinning down of the semiconductor wafer via its backside;
the depositing and etching of layers of material on its backside thus thinned, wherein narrow vertical trenches are etched into the wafer by its front face, before the bonding operation, these trenches extending into the wafer over a depth approximately equal to the residual semiconductor wafer thickness that will remain after the thinning operation, the trenches being filled with a conducting material isolated from the active layer and forming conducting vias between the front face and the backside of the thinned layer.

17. The process as claimed in claim 16, wherein the trenches are formed before other deposition and etching steps of electrically functional layers on the front face of the semiconductor wafer.

18. The process as claimed in claim 16, wherein the trench takes the form of an alignment marker visible from the backside after thinning in order to allow alignment of the patterns for etching of the layers on the backside with respect to the patterns for etching of layers on the front face.

19. The process as claimed in claim 16, wherein the metal layer is deposited onto the backside of the wafer after thinning, this layer being connected, by conducting vias formed within at least one narrow trench, to at least one conducting layer formed, prior to bonding the wafer onto the support substrate, on the front face of the wafer.

20. The process as claimed in claim 19, wherein the metal layer is a photo-masking layer designed to prevent light impinging on photosensitive parts within an image sensor formed on the wafer.

21. The process as claimed in claim 16, wherein layers of color filters are deposited onto the backside of the wafer after bonding and thinning.

22. The process as claimed in claim 21, wherein, after deposition of the color filters, the semiconductor wafer and its support substrate are bonded onto another, transparent, substrate and the support substrate is eliminated.

23. The process as claimed in claim 1, wherein the trenches have their internal walls coated with thin silicon oxide and are filled with polycrystalline silicon that is highly doped so as to be conducting.

24. The process according to claim 16, wherein the role of trench is to isolate laterally one portion of active layer from other portions of active layer, and notably to isolate a region of active layer situated underneath an external connection pad from the neighboring regions of active layer.

25. The process as claimed in claim 16, wherein the semiconductor wafer comprises a highly-doped silicon substrate coated with a more lightly doped epitaxial layer forming the active layer, of around 5 to 20 microns thickness, and in that the depth of the trenches is substantially equal to the thickness of the epitaxial layer.

26. A color image sensor comprising
a support substrate,
a thin silicon layer in which a matrix of photosensitive regions is formed,
etched layers on a front face of this silicon layer,
at least one metal layer and layers of color filters etched onto the other face, i.e. the backside, of the silicon layer,
narrow vertical trenches traversing the whole of the silicon layer, having their sidewalls coated with an insulating layer and that are filled with a conducting material.

27. The color image sensor as claimed in claim 11, wherein trench filled with conducting material forms a conducting via in contact at one side with the metal layer on the backside, and at the other with at least one conducting layer on the front face.

27. The color image sensor as claimed in claim 27, comprising a series of parallel vertical trenches disposed under the same contact pad for the external connection of the image sensor and electrically connected to this pad.

28. The color image sensor as claimed in claim 11, wherein vertical trench forms an isolation trench between two neighboring silicon regions of the silicon layer.

29. The color image sensor as claimed in claim 14, wherein the trench that forms an isolation trench completely surrounds a silicon region situated underneath a contact pad for the external connection of the image sensor.
